(19) United States
(12) Patent Application Publication
(10) Pub. No.: US 2005/0077981 A1
(43) Pub. Date: Apr. 14, 2005

(54) Radio frequency connector port with isolation function

(75) Inventors: Jackie Tsao, Chung-Ho City (TW); Lloyd Chen, Chung-Ho City (TW)

Correspondence Address: Ladas & Parry LLP, 26 West 61st Street, New York, NY, 10023, US

(73) Assignee: TAIWAN CABLE CONNECTION CORP

(21) Appl. No.: 10/956,381

(22) Filed: Oct. 1, 2004

(30) Foreign Application Priority Data
Oct. 8, 2003 (TW) 092218038

(51) Int. Cl. H03H 7/01

(52) U.S. Cl. 333/182; 333/185

(57) ABSTRACT

A radio frequency connector port includes a connector body, a conductor unit and an isolator unit. The connector body is formed with a receiving space that extends in an axial direction. The conductor unit is disposed in the receiving space and extends in the axial direction. The isolator unit is disposed in the receiving space around the conductor unit, and includes a first capacitor, a second capacitor spaced apart from the first capacitor in the axial direction, and an inductor disposed between and coupled electrically to the first and second capacitors.

### CROSS-REFERENCE TO RELATED APPLICATION

This application claims priority of Taiwanese application no. 092218038, filed on Oct. 8, 2003.

### BACKGROUND OF THE INVENTION

1. Field of the Invention

The invention relates to a connector port, more particularly to a radio frequency connector port with an isolation function.

2. Description of the Related Art

Referring to FIG. 1, a conventional one-to-many signal transmission device 9 is used for transmitting and conveying cable television signals (which are radio frequency signals) from a system end to client devices. As shown, the signal transmission device 9 includes a housing 90, and an input port 91 and a pair of output ports 921, 922 mounted on the housing 90. Radio frequency signals are fed into the signal transmission device 9 via the input port 91, undergo signal distribution processing within the housing 90, and are outputted via the output ports 921, 922. The input port 91 includes a port body 911 that extends into the housing 90, an insulator body 912 mounted in the port body 911, and a terminal clamp 913 mounted in the insulator body 912 for establishing electrical connection with a terminal (not shown) of a transmission line (not shown) that carries radio frequency signals.

An isolator unit 93 is disposed in the housing 90, and is connected to the input port 91. The isolator unit 93 includes a plurality of capacitors 931, a plurality of cylindrical ferrite cores 932, and a copper cable 933. The capacitors 931 are grounded and are connected electrically to the copper cable 933. Particularly, to connect the capacitors 931 to the copper cable 933, segments of an insulator sheath of the copper cable 933 are peeled to permit soldering of the capacitors 931 to a conductive core of the copper cable 933. The ferrite cores 932 are sleeved on the copper cable 933, and cooperate with the latter to form inductors that are connected in parallel with the capacitors 931.

The main purpose of the isolator unit 93 is to isolate high voltages and minimize radio frequency interference. To this end, European safety standards that must be satisfied by the isolator unit 93 include the galvanic test (i.e., EN50083-1) and the radio frequency interference or RFI test (i.e., EN50083-2 Class A). According to the requirements of EN50083-1, when the system voltage input is 2120 VDC, the current leakage should not exceed 0.7 mA. Moreover, when the voltage at the client device is 230 VAC, the current leakage must not exceed 8.0 mA. According to the requirements of EN50083-2 Class A, when the frequency band is 30-1000 MHz, radio frequency interference must not exceed 85 dB.

It is noted that the minimum total length required of the isolator unit 93 so as to enable the latter to possess the aforesaid desired characteristics is about 10 centimeters. As such, the signal transmission device 9 must have sufficient space to accommodate the isolator unit 93, thereby resulting in a corresponding increase in the size of the signal transmission device 9. Moreover, manufacturing of the isolator unit 93 is both laborious and costly.

### SUMMARY OF THE INVENTION

Therefore, the object of the present invention is to provide a radio frequency connector port that can overcome the aforesaid drawbacks associated with the prior art.

According to one aspect of the invention, a radio frequency connector port comprises a connector body formed with a receiving space that extends in an axial direction, a conductor unit disposed in the receiving space and extending in the axial direction, and an isolator unit disposed in the receiving space around the conductor unit. The isolator unit includes a first capacitor, a second capacitor spaced apart from the first capacitor in the axial direction, and an inductor disposed between and coupled electrically to the first and second capacitors. The connector body includes a first body part that confines a first portion of the receiving space and that has the first capacitor disposed therein, and a second body part that confines a second portion of the receiving space, that has the second capacitor disposed therein, and that is coupled threadedly to the first body part. The inductor extends simultaneously into the first and second portions of the receiving space.

According to another aspect of the invention, a radio frequency connector port comprises a connector body formed with a receiving space that extends in an axial direction, a conductor unit disposed in the receiving space and extending in the axial direction, and an isolator unit disposed in the receiving space around the conductor unit. The isolator unit includes a first capacitor, a second capacitor spaced apart from the first capacitor in the axial direction, and an inductor disposed between and coupled electrically to the first and second capacitors. The inductor includes a copper tube and a cylindrical ferrite core disposed around the copper tube. The copper tube extends in the axial direction through the first and second capacitors. The ferrite core is disposed between the first and second capacitors. The radio frequency connector port further comprises a first retainer for retaining and connecting electrically the first capacitor to the copper tube, and a second retainer for retaining and connecting electrically the second capacitor to the copper tube.

### BRIEF DESCRIPTION OF THE DRAWINGS

Other features and advantages of the present invention will become apparent in the following detailed description of the preferred embodiments with reference to the accompanying drawings, of which:

FIG. 1 is a partly exploded perspective view of a conventional signal transmission device;

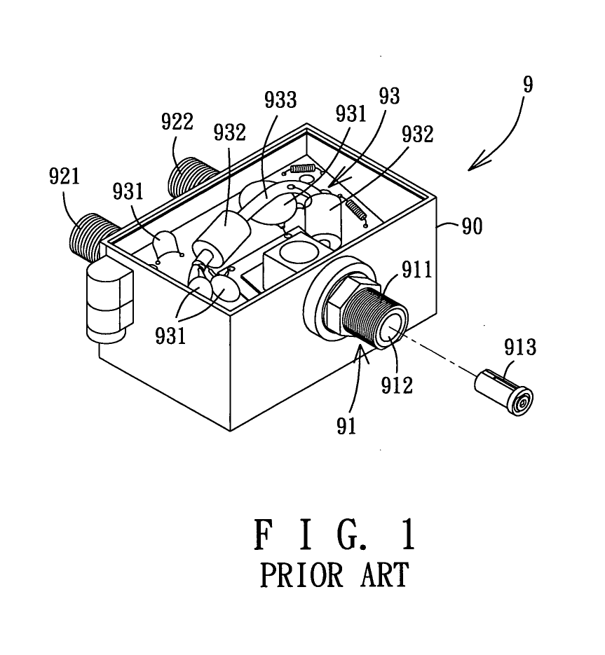

FIG. 2 is an exploded perspective view of a preferred embodiment of a radio frequency connector port according to the present invention that is to be applied to a signal transmission device;

FIG. 3 is an exploded schematic sectional view of the preferred embodiment;

FIG. 4 is an assembled schematic sectional view of the preferred embodiment;

FIG. 5 is an exploded schematic sectional view of a modified preferred embodiment of this invention;

FIG. 6 is a plot to illustrate measured insertion loss at different frequencies when a conventional isolator unit is applied to a signal transmission device; and

FIG. 7 is a plot to illustrate measured insertion loss at different frequencies when the present invention is applied to a signal transmission device.

### DETAILED DESCRIPTION OF THE PREFERRED EMBODIMENTS

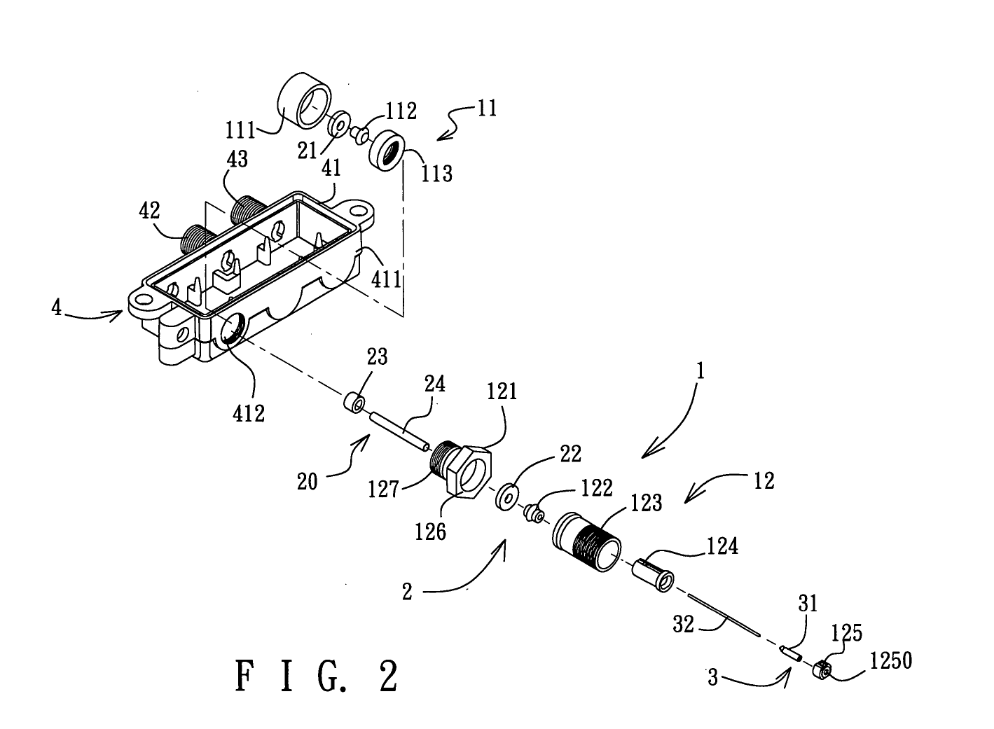

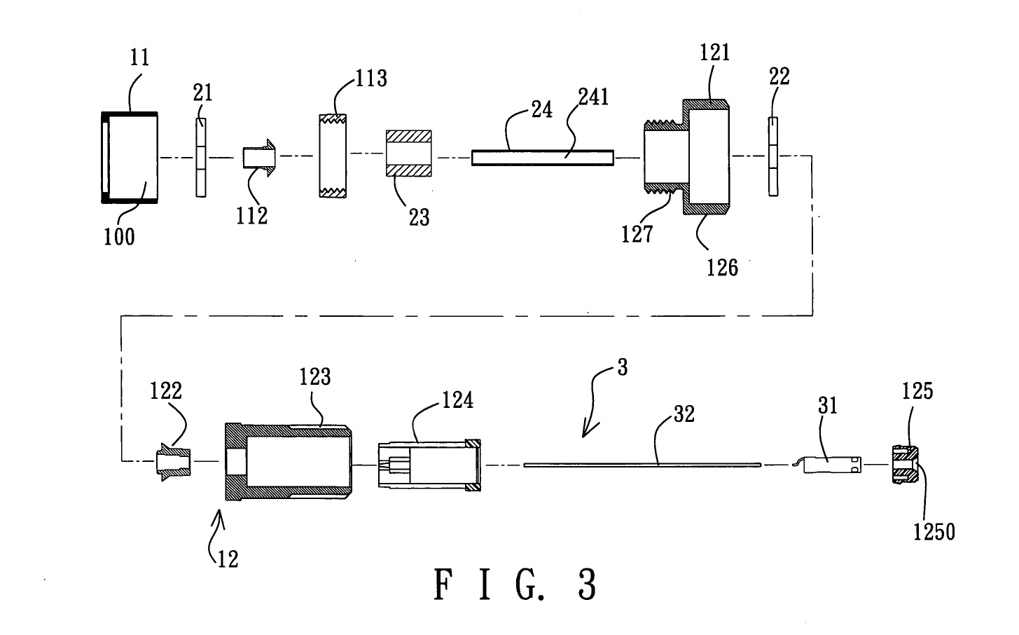

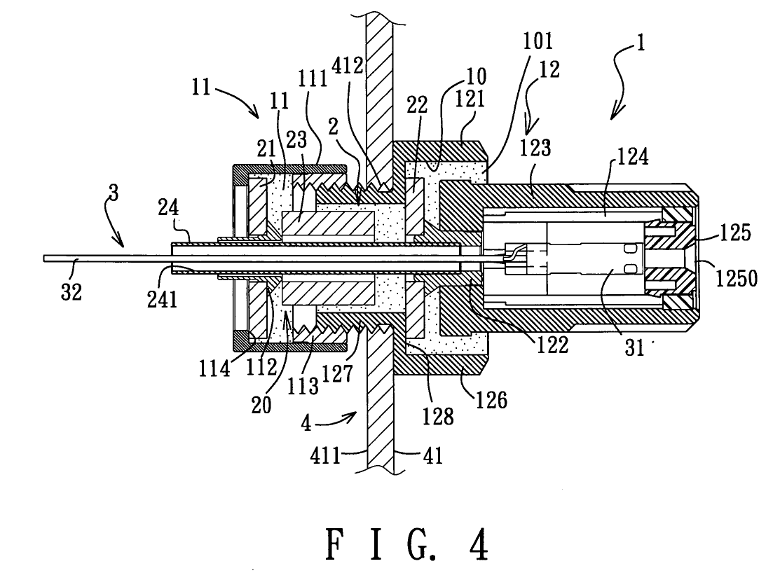

Referring to FIGS. 2 to 4, a preferred embodiment of a radio frequency connector port according to the present invention is shown to include a connector body 1, a conductor unit 3, and an isolator unit 2. The preferred embodiment of this invention is adapted for use as an input port of a one-to-two signal transmission device 4 that includes a housing 41 and a pair of output ports 42, 43. The housing 41 has a lateral wall 411 that is formed with an internally threaded hole 412 for mounting the radio frequency connector port of this invention on the housing 41.

The connector body 1 is formed with a receiving space 10 that extends in an axial direction. In this embodiment, the connector body 1 includes a conductive first body part 11 that confines a first portion 100 of the receiving space 10, and a conductive second body part 12 that confines a second portion 101 of the receiving space 10 and that is coupled threadedly to the first body part 11. The first and second body parts 11, 12 are to be disposed on inner and outer sides of the lateral wall 411 of the housing 41, respectively.

The first body part 11 includes a first tubular body 111, a radial inward annular flange 114 formed in one end of the first tubular body 111, and a first coupling member 113 fixed in the other end of the first tubular body 111 and formed with an internal thread. The second body part 12 includes a second tubular body 121 and a second coupling member 123. The second tubular body 121 includes a narrower section 127 and a wider section 126 that extends from the narrower section 127. The narrower section 127 is formed with an external thread, engages threadedly the hole 412 in the lateral wall 411 of the housing 41, and further engages threadedly the first coupling member 113, thereby mounting the first and second body parts 11, 12 on the housing 41 of the signal transmission device 4.

The conductor unit 3 is disposed in the receiving space 10, and extends in the axial direction. The conductor unit 3 includes a terminal clamp 31 and a transmission wire 32 connected at one end to the terminal clamp 31. The radio frequency connector port further comprises an insulation member 124 disposed in the second coupling member 123 of the second body part 12 of the connector body 1 around the terminal clamp 31, and an insulation end piece 125 disposed in one end of the second coupling member 123 and abutting against the insulation member 124. The insulation end piece 125 is formed with a terminal through hole 1250. The second coupling member 123 and the conductor unit 3 are configured to permit connection of the radio frequency connector port to an external connector selected from the group consisting of a BNC connector, an F-type connector, an IEC connector, and an N-type connector.

The isolator unit 2 is disposed in the receiving space 10 around the conductor unit 3, and includes a first capacitor 21 disposed in the first portion 100 of the receiving space 10, a second capacitor 22 disposed in the second portion 101 of the receiving space 10 and spaced apart from the first capacitor 21 in the axial direction, and an inductor 20 disposed between and coupled electrically to the first and second capacitors 21, 22. In this embodiment, each of the first and second capacitors 21, 22 is a ring capacitor. The inductor 20 extends simultaneously into the first and second portions 100, 101 of the receiving space 10, and includes a copper tube 24 that extends in the axial direction through the first and second capacitors 21, 22, and a cylindrical ferrite core 23 disposed around the copper tube 24 between the first and second capacitors 21, 22. The copper tube 24 defines a tube passage 241. The transmission wire 32 of the conductor unit 3 extends through the tube passage 241 of the copper tube 24 of the isolator unit 2.

A first retainer 112 retains and connects electrically the first capacitor 21 to the copper tube 24. A second retainer 122 retains and connects electrically the second capacitor 22 to the copper tube 24.

During assembly, the first capacitor 21 is disposed in the first portion 100 of the receiving space 10 and abuts against the annular flange 114 in the first tubular body 111. Then, a rod section of the first retainer 112 is passed through the first capacitor 21 such that a head section of the first retainer 112 presses the first capacitor 21 against the annular flange 114. Engagement between the first capacitor 21 and the first retainer 112 may be enhanced by soldering and by filling the first portion 100 of the receiving space 10 with an amount of an epoxy resin. Thereafter, the first coupling member 113 is fixed in the first tubular body 111.

Then, after fixing the insulation member 124 and the insulation end piece 125 in the second coupling member 123, and after connecting the terminal clamp 31 to the transmission wire 32, the terminal clamp 31 is extended into the insulation member 124 such that the transmission wire 32 extends out of the second coupling member 123. A tubular section of the second retainer 122 is extended into and engages one end of the second coupling member 123 opposite to the insulation end piece 125. After extending the transmission wire 32 through the tube passage 241 of the copper tube 24 of the isolator unit 2, one end of the copper tube 24 is fixed in the second retainer 122. Subsequently, the second capacitor 22 is disposed in the second portion 101 of the receiving space 10, i.e., in the wider section 126 of the second tubular body 121, and abuts against a shoulder 128 in the second tubular body 121 at a junction of the narrower and wider sections 127, 126. The copper tube 24 is extended through the second capacitor 22 and the narrower section 127 of the second tubular body 121, and a rod section of the second retainer 122 is inserted into the second capacitor 22 such that a flange section of the second retainer 122 presses the second capacitor 22 against the shoulder 128. Subsequently, the wider section 126 of the second tubular body 121 is filled with an amount of an epoxy resin around the second coupling member 123 such that the second coupling member 123 is secured to the second tubular body 121.

After the narrower section 127 of the second tubular body 121 is filled with an amount of an epoxy resin around the copper tube 24, the ferrite core 23 is extended into the narrower section 127 so as to be sleeved on the copper tube 24. Finally, the narrower section 127 of the second tubular body 121 is threaded through the hole 412 in the lateral wall 411 of the housing 41, and the first coupling member 113 of the first body part 11 is coupled threadedly to the narrower section 127 of the second tubular body 121, with the copper tube 24 and the transmission wire 32 extending through the second capacitor 21 and the first body part 11. The radio frequency connector port is secured on the housing 41 of the signal transmission device 4 at this time.

It should be noted herein that electrical connections among the aforesaid components can be enhanced by soldering. Moreover, mounting of the radio frequency connector port of this invention on the signal transmission device 4 should not be limited to the arrangement of this embodiment, i.e., in the hole 412 of the lateral wall 411 of the housing 41. In practice, assembly of the radio frequency connector port to the signal transmission device 4 can be altered in ways known to those skilled in the art to meet actual requirements.

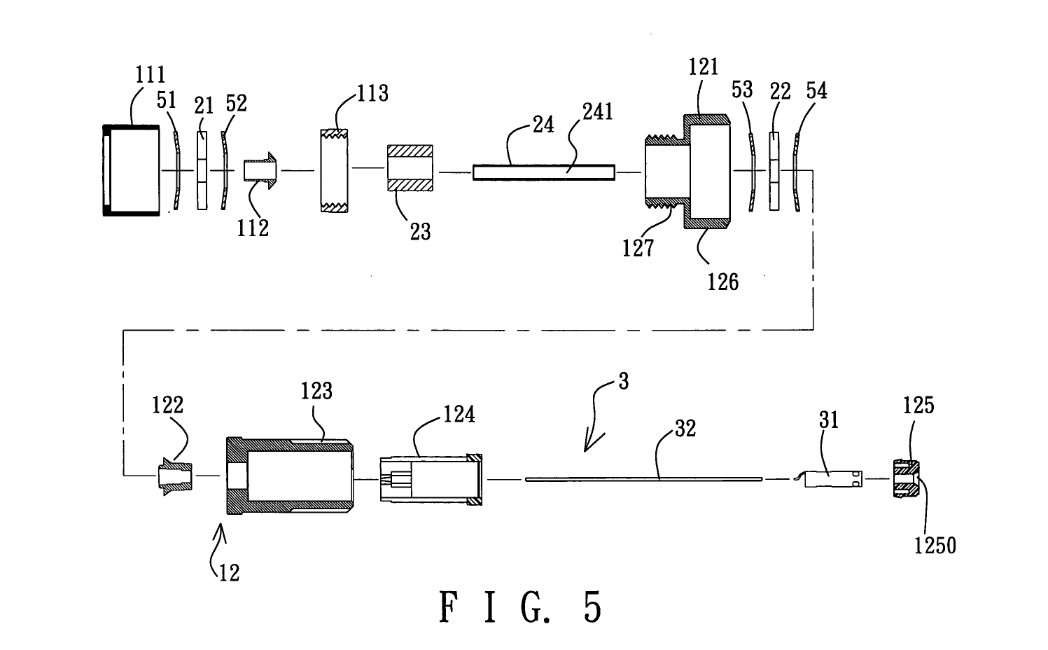

Furthermore, as shown in FIG. 5, in a modified embodiment of this invention, a plurality of conductive resilient plates are provided to further enhance electrical connections. Particularly, a pair of resilient plates 51, 52 sandwich the first capacitor 21, whereas another pair of resilient plates 53, 54 sandwich the second capacitor 22.

In the present invention, since the conductor unit 3 extends through the various components of the isolator unit 2, when a terminal (not shown) of an external connector (not shown) carrying radio frequency signals is inserted through the terminal through hole 1250 so as to transmit the signals to the signal transmission device 4 via the conductor unit 3, the isolator unit 2 provides the desired high voltage isolation and radio frequency interference screening characteristics. Moreover, a clearance is present between the transmission wire 32 and the copper tube 24 to ensure good signal transmission quality.

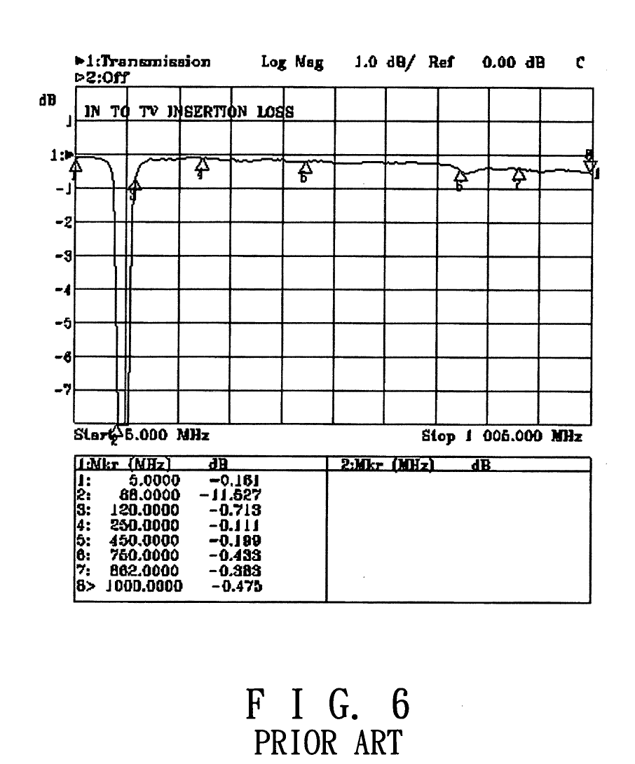

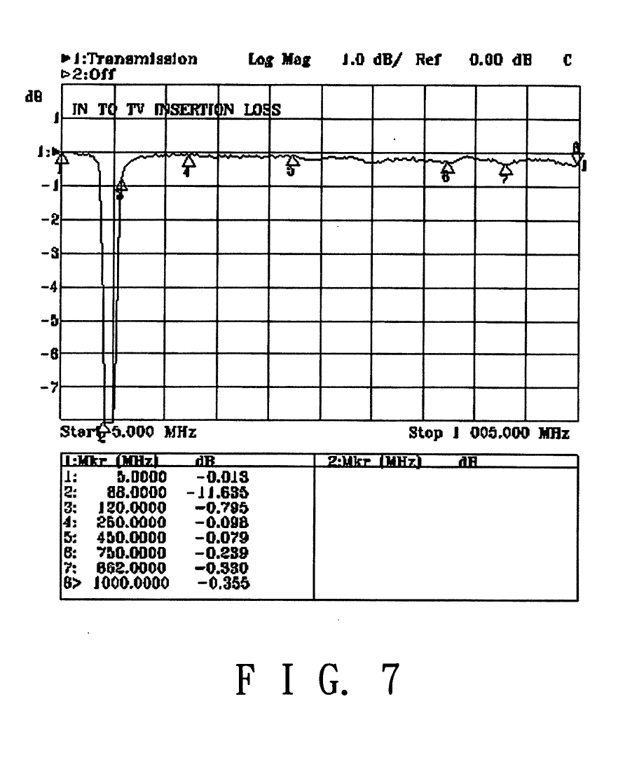

Insertion loss is an inherent problem of the signal transmission device 4. In general, a lower insertion loss indicates better signal transmission quality. FIGS. 6 and 7 are plots to illustrate measured insertion loss at different frequencies using the signal transmission device 9 with the conventional isolator unit 93, and the signal transmission device 4 with the radio frequency connector port of this invention, respectively. Based on the results shown in FIGS. 6 and 7, better signal transmission performance is obtained when the radio frequency connector port of this invention is in use.

Furthermore, since the isolator unit 2 is built into the radio frequency connector port of this invention, the size of the signal transmission device 4 can be made smaller as compared to the prior art. In addition, the drawbacks of high labor and material costs associated with the use of the isolator unit 93 in the conventional signal transmission device 9 can be alleviated.

While the present invention has been described in connection with what is considered the most practical and preferred embodiments, it is understood that this invention is not limited to the disclosed embodiments but is intended to cover various arrangements included within the spirit and scope of the broadest interpretation so as to encompass all such modifications and equivalent arrangements.

1. A radio frequency connector port comprising:
a connector body formed with a receiving space that extends in an axial direction;
a conductor unit disposed in said receiving space and extending in the axial direction; and
an isolator unit disposed in said receiving space around said conductor unit, said isolator unit including a first capacitor, a second capacitor spaced apart from said first capacitor in the axial direction, and an inductor disposed between and coupled electrically to said first and second capacitors;
said connector body including a first body part that confines a first portion of said receiving space and that has said first capacitor disposed therein, and a second body part that confines a second portion of said receiving space, that has said second capacitor disposed therein, and that is coupled threadedly to said first body part;
said inductor extending simultaneously into said first and second portions of said receiving space.

2. The radio frequency connector port as claimed in claim 1, wherein said conductor unit includes a terminal clamp and a transmission wire connected at one end to said terminal clamp and extending through said isolator unit.

3. The radio frequency connector port as claimed in claim 2, further comprising an insulation member disposed in said connector body around said terminal clamp.

4. A radio frequency connector port comprising:
a connector body formed with a receiving space that extends in an axial direction;
a conductor unit disposed in said receiving space and extending in the axial direction;
an isolator unit disposed in said receiving space around said conductor unit, said isolator unit including a first capacitor, a second capacitor spaced apart from said first capacitor in the axial direction, and an inductor disposed between and coupled electrically to said first and second capacitors,
said inductor including a copper tube and a cylindrical ferrite core disposed around said copper tube, said copper tube extending in the axial direction through said first and second capacitors, said ferrite core being disposed between said first and second capacitors;
a first retainer for retaining and connecting electrically said first capacitor to said copper tube; and
a second retainer for retaining and connecting electrically said second capacitor to said copper tube.

5. The radio frequency connector port as claimed in claim 4, wherein each of said first and second capacitors is a ring capacitor.
